(19) United States
(12) Patent Application Publication
(10) Pub. No.: US 2002/0039031 A1
(43) Pub. Date: Apr. 4, 2002

(54) Intellectual testing system for testing packages

(76) Inventor: Hung-Tse Chiang, Hsinchu (TW)

Correspondence Address: J. C. PATENTS INC., 4 VENTURE, Suite 250, Irvine, CA, 92618, US

(21) Appl. No.: 09/490,725

(22) Filed: Jan. 25, 2000

(30) Foreign Application Priority Data
Jan. 10, 2000 (TW) 89100263

(51) Int. Cl. G01R 31/02

(52) U.S. Cl. 324/759

(57) ABSTRACT

An intellectual tape carrier package (TCP) testing system is used for testing IC samples. The intellectual TCP testing system has a maim test unit, a hardware interface, and a recorder. The main test unit is used to test all packages in a sequence without punching away those packages indicated as failure. The test results with respect to the packages are recorded into the recorder through the hardware interface that is coupled between the main test unit and the recorder. The test results allows engineers to analyze the failed IC samples and retest them, so as to prevent a misjudgment from occurring.

### CROSS-REFERENCE TO RELATED APPLICATION

This application claims the priority benefit of Taiwan application serial no. 89100263, filed Jan. 10, 2000.

### BACKGROUND OF THE INVENTION

1. Field of Invention

The present invention relates to semiconductor equipment. More particularly, the present invention relates to an intellectual testing system for testing packages, particularly suitable for uses in semiconductor package test.

2. Description of Related Art

In semiconductor fabrication, as IC packages have been fully done, a performance test for the integrated circuit (IC) packages, such as IC chips, is necessary, so as to ensure the quality of the IC chips, or called the IC samples. FIG. 1 is a system drawing, schematically illustrating a conventional tape carrier package testing system. In FIG. 1, the tape carrier package (TCP) testing system includes a untested reel 10, a tested reel 20, a sample under test (DUT) unit 30, a punch head 40 and a belt conveyor 50.

On the conventional TCP testing system, those samples to be tested are mounted on the belt conveyor 50 by glue, soldering, or any mounting means. The belt conveyor 50 with the samples to be tested, such as the IC devices, is usually wound on the untested reel 10. Then, the belt conveyor 50 conveys the samples following a rout so that each of the samples passes through the DUT unit 30 for test. After test, the samples passing the test remain on the belt conveyor 50 and are wound to the tested reel 20. The samples failed the test are removed from the belt conveyor 50 by the punch head 40.

FIG. 2 is a drawing, schematically illustrating a conventional manner to mount samples on the belt conveyor. In FIG. 2, several samples, such as IC samples 52, are regularly mounted on the belt conveyor 50. The samples 52 are conveyed to the DUT unit 30 for test. If test result of any sample 52 indicates a failure, this sample 52 is removed by the punch head 30 when the sample 52 reaches the location of the punch head 40. In other words, the samples wound up on the tested reel 20 have passed the test and can be used with the designed functions.

However, the package testing system may be affected by the environmental conditions or the actual operation issue. This may result in a misjudgment on the IC samples. Many of those failed IC samples may still be acceptable but are punched away due to the misjudgment. As a result, the is an avoidable loss in fabrication cost.

### SUMMARY OF THE INVENTION

The invention provides an intellectual testing system for testing packages with abilities to record all test results of the packages.

The invention provides an intellectual testing system, which can record all test results with respect to all packages without punching the failed packages away immediately. According to the failure results, engineers can analyze those failed packages and retest them, so that the misjudgment on the package is effectively avoided.

As embodied and broadly described herein, the invention provides an intellectual testing system with a TCP type for testing package. The intellectual testing system includes a maim test unit, a hardware interface, and a recorder. The main test unit is used to test all packages in a sequence without punching away those packages indicated as failure. The test results with respect to the packages are recorded into the recorder through the hardware interface that is coupled between the main test unit and the recorder.

According to the test results, engineers can collect those failed packages and retest them to effectively reduce the probability of misjudgment. The fabrication cost can also be effectively reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a system drawing, schematically illustrating a conventional tape carrier package testing system;

FIG. 2 is a drawing, schematically illustrating a conventional manner to mount samples on the belt conveyor; and

FIG. 3 is a drawing, schematically illustrating an intellectual TCP testing system, according to one preferred embodiment of the invention.

### DESCRIPTION OF THE PREFERRED EMBODIMENTS

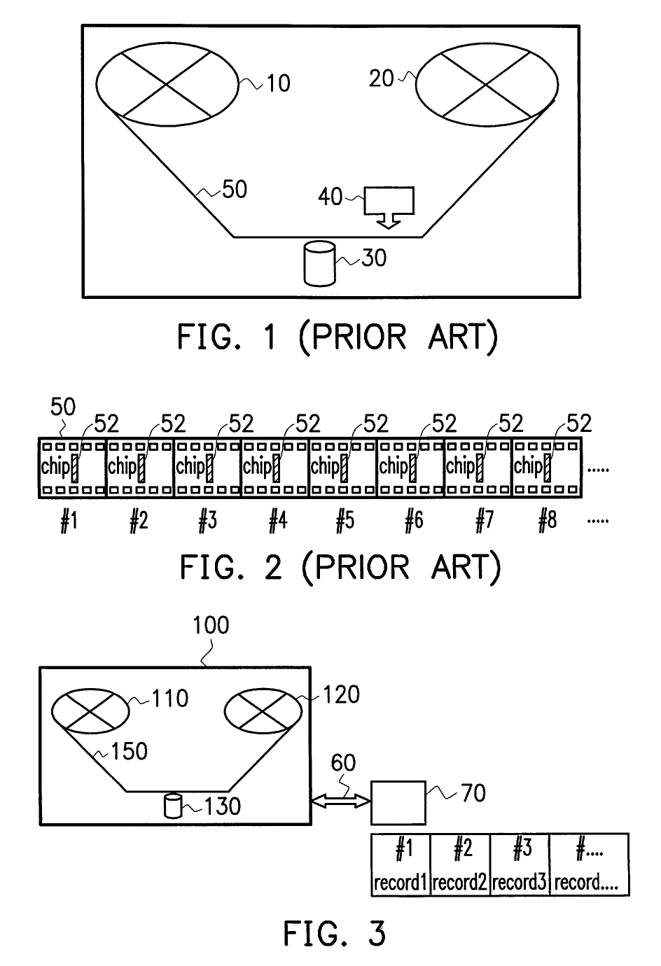

FIG. 3 is a drawing, schematically illustrating an intellectual TCP testing system, according to one preferred embodiment of the invention. In FIG. 3, the intellectual testing system with, for example, a TCP type includes a main test unit 100, a hardware interface 60, and a recorder 70. The hardware interface 60 and the recorder 70 are the main difference from the conventional TCP testing system. The hardware interface 60 is coupled between the main test unit 100 and the recorder 70. The recorder can be, for example, a computer or a counter to record test results with respect to the IC samples 52. The main test unit 100 is similar to the conventional TCP testing system as shown in FIG. 1, but it is not necessary to include the punch head 140 since the IC samples are not punched away at this stage in the manner of the invention. The failed IC samples can be dropped later after retested.

The main test unit 100 includes an untested reel 110, a tested reel 120, a DUT unit 130, and a belt conveyor 150. Like the mounting manner of FIG. 2, the IC samples to be tested are mounted on the belt conveyor 150. The belt conveyor 150 conveys the IC samples 52 for test at the DUT 130 and then the belt conveyor 150 with the IC samples 52 is wound to the tested reel 120 without punching away any IC samples. Each of the IC samples on the belt conveyor 150 is assigned with an identification code, and the test results with respect to the IC samples are stored in the recorder 70 through the hardware interface. The identification code, for example, can be assigned by the hardware interface 60 or the recorder 70, or any means to identify the IC samples. The test procedure may include several items. Each item is represented, for example, by one bin or a similar manner. Each of the test result may includes several bins. Thereby, all test results are accordingly recorded in the recorder 70. Engineers can analyze the test results for those IC samples which have failed in the test. The reason causing the misjudgment can also be found after analyses. A retest for those failed IC samples may be performed again if any misjudgment or environmental factors occur, resulting in bias of the test results. The actually failed IC samples can be dropped away, for example, according to the tested status for each IC samples. The fabrication cost therefore can be reduced.

In conclusion, the invention provides an intellectual testing system for testing packages with abilities to record all test results of the packages. The invention also provides an intellectual testing system, which can record all test results with respect to all packages without punching the failed packages away immediately. According to the failure results, engineers can analyze those failed packages and retest them, so that the misjudgment on the package is effectively avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An intellectual testing system for test integrated circuit (IC) samples, the testing system comprising:
a tape carrier package (TCP) test unit, which is used to test a plurality of IC samples and produce a plurality of test results with respect to the IC samples, wherein the IC samples are not punched away;
a hardware interface, coupled to the TCP test unit to obtain the test results corresponding to the IC samples, respectively; and
a recorder, coupled to the hardware interface to receive and record the test results with respect to the IC samples.

2. The testing system of claim 1, wherein test results comprise a pass-or-failure information.

3. The testing system of claim 1, wherein test results comprise information to indicate any failure one of tested items of one test procedure.

4. The testing system of claim 1, wherein the recorder comprises a computer.

5. The testing system of claim 1, wherein the recorder comprises a counter.

6. An intellectual testing system for test integrated circuit (IC) samples, the testing system comprising:
a tape carrier package (TCP) test unit, which is used to test a plurality of IC samples and produce a plurality of test results with respect to the IC samples, wherein the IC samples are not punched away;
a hardware interface, which may be externally coupled to the TCP test unit or be included in the TCP test unit, so that the IC samples are respectively assigned with identification codes, and the test results with the identification codes are exported through the hardware interface; and
a recorder, coupled to the hardware interface to receive and record the test results with the identification codes with respect to the IC samples.

7. The testing system of claim 6, wherein the test results comprise a pass-or-failure information.

8. The testing system of claim 6, wherein test results comprise information to indicate any failure one of tested items of one test procedure.

9. The testing system of claim 6, wherein the recorder comprises a computer.

10. The testing system of claim 6, wherein the recorder comprises a counter.
